(19) United States
(12) Patent Application Publication
(10) Pub. No.: US 2015/0188037 A1
(43) Pub. Date: Jul. 2, 2015

(54) MAGNETORESISTIVE RANDOM ACCESS MEMORY DEVICES AND METHODS OF MANUFACTURING THE SAME

(71) Applicants: Kyung-Tae NAM, Suwon-si (KR); Kil-Ho LEE, Hwaseong-si (KR)

(72) Inventors: Kyung-Tae NAM, Suwon-si (KR); Kil-Ho LEE, Hwaseong-si (KR)

(21) Appl. No.: 14/453,110

(22) Filed: Aug. 6, 2014

(30) Foreign Application Priority Data
Dec. 26, 2013 (KR) 10-2013-0163720

(51) Int. Cl. H01L 43/12; H01L 43/08; H01L 27/22; H01L 43/02

(52) U.S. Cl. CPC H01L 43/12; H01L 43/02; H01L 43/08; H01L 27/228

(57) ABSTRACT

In a method of manufacturing an MRAM device, a lower electrode, a first pinning layer pattern, a tunnel barrier layer pattern and a free layer pattern sequentially stacked on a substrate may be formed. A first insulating interlayer may be formed on the substrate to cover the lower electrode, the first pinning layer pattern, the tunnel barrier layer pattern and the free layer pattern. The first insulating interlayer may be etched to form a recess exposing a top surface of the free layer pattern. A second pinning layer pattern may be formed to fill at least a portion of the recess. A wiring may be formed on the second pinning layer pattern.

### CROSS-REFERENCE TO RELATED APPLICATION

This application claims priority under 35 USC §119 to Korean Patent Application No. 10-2013-0163720, filed on Dec. 26, 2013, in the Korean Intellectual Property Office (KIPO), the contents of which are herein incorporated by reference in their entirety.

### BACKGROUND

1. Field

Example embodiments relate to magnetoresistive random access memory (MRAM) devices and methods of manufacturing the same.

2. Description of the Related Art

An MRAM device is a non-volatile memory device, and may include a magnetic tunnel junction (MTJ) structure. The MTJ structure may include a fixed layer pattern structure, a tunnel barrier layer pattern and a free layer pattern sequentially stacked, which may be formed by a physical etching process such as ion sputtering. However, a magnetic material of the fixed layer pattern structure may be re-sputtered during the physical etching process, so as to be attached onto a sidewall of the MTJ structure. Thus, the MTJ structure may be deteriorated.

### SUMMARY

Example embodiments provide an MRAM device having good electrical characteristics.

Example embodiments provide a method of manufacturing an MRAM device having good electrical characteristics.

According to example embodiments, there is provided a method of manufacturing an MRAM device. In the method, a lower electrode, a first pinning layer pattern, a tunnel barrier layer pattern and a free layer pattern sequentially stacked on a substrate may be formed. A first insulating interlayer may be formed on the substrate to cover the lower electrode, the first pinning layer pattern, the tunnel barrier layer pattern and the free layer pattern. The first insulating interlayer may be etched to form a recess exposing a top surface of the free layer pattern. A second pinning layer pattern may be formed to fill at least a portion of the recess. A wiring may be formed on the second pinning layer pattern.

In example embodiments, the second pinning layer pattern may be formed to have a thickness thicker than the thickness of the first pinning layer pattern.

In example embodiments, the first and second pinning layer patterns may have magnetization directions that are opposite to each other.

In example embodiments, the recess may extend in one direction, and the wiring may be formed on the second pinning layer pattern to fill a remaining portion of the recess.

In example embodiments, when the wiring is formed, an upper portion of the first insulating interlayer may be planarized until a top surface of the first insulating interlayer is coplanar with a top surface of the second pinning layer pattern. A second insulating interlayer having an opening, which may expose the top surface of the second pinning layer pattern and extend in one direction, may be formed on the planarized first insulating interlayer. The wiring may be formed to fill the opening.

In example embodiments, when the lower electrode, the first pinning layer pattern, the tunnel barrier layer pattern and the free layer pattern are formed, a lower electrode layer, a first pinning layer, a tunnel barrier layer, a free layer and a hard mask may be sequentially formed on the substrate. The free layer, the tunnel barrier layer, the first pinning layer and the lower electrode layer may be sequentially patterned using the hard mask as an etching mask.

In example embodiments, after patterning the free layer, the tunnel barrier layer, the first pinning layer and the lower electrode layer, a first spacer may be formed to surround sidewalls of the lower electrode, the first pinning layer pattern, the tunnel barrier layer pattern and the free layer pattern.

In example embodiments, when the lower electrode, the first pinning layer pattern, the tunnel barrier layer pattern and the free layer pattern are formed, the lower electrode and the first pinning layer pattern may be sequentially stacked on the substrate. A third insulating interlayer may be formed to surround the sidewalls of the lower electrode and the first pinning layer pattern. A tunnel barrier layer, a free layer and the hard mask may be formed on the third insulating interlayer and the first pinning layer pattern. The free layer and the tunnel barrier layer may be sequentially patterned using the hard mask as an etching mask.

In example embodiments, after patterning the free layer and the tunnel barrier layer, a second spacer may be formed on the third insulating interlayer to surround the sidewalls of the free layer pattern and the tunnel barrier layer pattern.

According to example embodiments, an MRAM device is provided. The MRAM device may include a lower electrode, a MTJ structure and a wiring sequentially stacked on the substrate. The MTJ structure may be formed to include a first pinning layer pattern having a first thickness, a tunnel barrier layer pattern, a free layer pattern, a second pinning layer pattern having a second thickness sequentially stacked on the lower electrode. The second thickness may be thicker than the first thickness.

In example embodiments, the wiring may extend in a direction.

In example embodiments, the second pinning layer pattern may extend in the same direction as the direction of the wiring.

In example embodiments, the first and second pinning layer patterns may have magnetization directions that are opposite to each other.

In example embodiments, the wiring may contact a top surface of the MTJ structure.

In example embodiments, the MRAM device may further comprise a spacer covering at least sidewalls of the tunnel barrier layer pattern and the free layer pattern.

According to example embodiments, the MTJ structure may be formed by the following steps. A lower electrode, a first pinning layer pattern, a tunnel barrier layer pattern and a free layer pattern may be sequentially formed on a substrate by a physical etching process. A second pinning layer pattern may be formed on the free layer pattern by a damascene process or a physical etching process. A wiring contacting the second pinning layer pattern may be formed thereon. Thus, a height of the layers, which may be patterned at each physical etching process, may be minimized when the MTJ structure is formed, and thus an attachment of a magnetic material onto a sidewall of the MTJ structure may be reduced.

Moreover, the first and second pinning layer patterns, which have magnetization directions that are substantially opposite to each other, may be formed beneath and above the free layer pattern, respectively, and thus an upper electrode may not be formed on the free layer pattern, and the deterioration of magnetic characteristics of the MRAM device including the MTJ structure may be reduced, or alternatively prevented.

Example embodiments also related to a method of manufacturing a magnetoresistive random access memory (MRAM) device including forming a lower electrode on a substrate, forming a material tunnel junction (MTJ) structure, forming a hard mask on the MTJ structure, patterning the MTJ structure and the lower electrode by using the hard mask, forming a first insulating interlayer on the substrate and the patterned lower electrode, MTJ structure and hard mask, etching the first insulating interlayer to form a first recess exposing a surface of the MTJ structure, forming a second pinning layer pattern to fill at least a portion of the recess, and forming a wiring on the second pinning layer pattern.

### BRIEF DESCRIPTION OF THE DRAWINGS

Example embodiments will be more clearly understood from the following detailed description taken in conjunction with the accompanying drawings. FIGS. 1 to 22 represent non-limiting, example embodiments as described herein.

FIG. 1 is a cross-sectional view illustrating an MRAM device in accordance with example embodiments;

FIGS. 2 to 10 are cross-sectional views illustrating a method of manufacturing an MRAM device in accordance with example embodiments;

FIG. 11 is a cross-sectional view illustrating an MRAM device in accordance with example embodiments;

FIGS. 12 to 13 are cross-sectional views illustrating a method of manufacturing an MRAM device in accordance with example embodiments;

FIGS. 14 to 16 are cross-sectional views illustrating a method of manufacturing an MRAM device in accordance with example embodiments;

FIG. 17 is a cross-sectional view illustrating an MRAM device in accordance with example embodiments;

FIGS. 18 to 21 are cross-sectional views illustrating a method of manufacturing an MRAM device in accordance with example embodiments; and

FIG. 22 is a cross-sectional view illustrating an MRAM device in accordance with example embodiments.

### DESCRIPTION OF EXAMPLE EMBODIMENTS

Various example embodiments will be described more fully hereinafter with reference to the accompanying drawings, in which some example embodiments are shown. The present inventive concepts may, however, be embodied in many different forms and should not be construed as limited to the example embodiments set forth herein. Rather, these example embodiments are provided so that this description will be thorough and complete, and will fully convey the scope of the present inventive concepts to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which these inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In the drawing figures, the dimensions of layers and regions may be exaggerated for clarity of illustration. Like reference numerals refer to like elements throughout. The same reference numbers indicate the same components throughout the specification.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

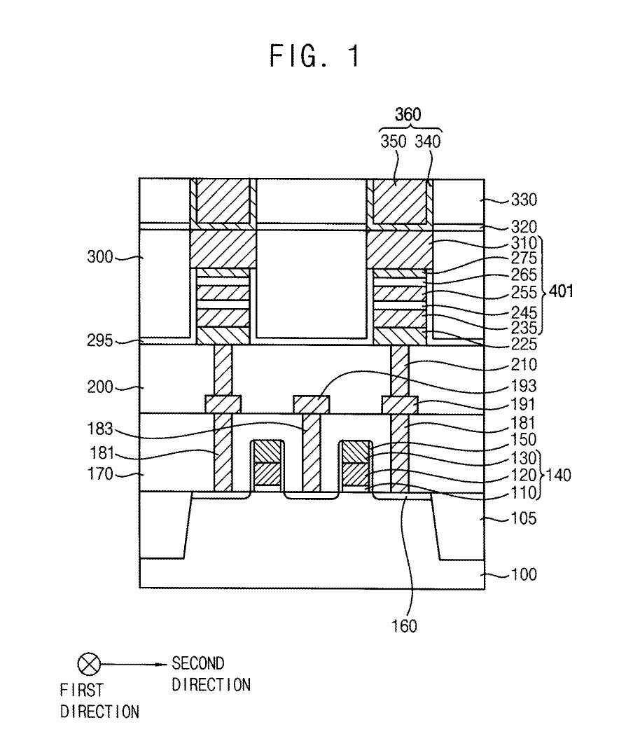

FIG. 1 is a cross-sectional view illustrating an MRAM device in accordance with example embodiments.

Referring to FIG. 1, the MRAM device may include a transistor having a lower electrode 225, a first magnetic tunnel junction (MTJ) structure 401 and a wiring 360.

The transistor may include a gate structure 140 on a substrate 100 and an impurity region 160 at an upper portion of the substrate 100 adjacent to the gate structure 140. The gate structure 140 may include a gate insulation layer pattern 110, a gate electrode 120 and a mask 130 sequentially stacked on the substrate 100, and a first spacer 150 may surround a sidewall of the gate structure 140.

The gate insulation layer pattern 110 may include an oxide, e.g., silicon oxide. The gate electrode 120 may include a conductive material, e.g., a metal such as tungsten (W) and/or polysilicon doped with impurities. The mask 130 and the first spacer 150 may include a nitride, e.g., silicon nitride.

The impurity region 160 may include, e.g., n-type impurities such as phosphorus, arsenic, etc., or p-type impurities such as boron, gallium, etc., and may serve as source/drain regions of the transistor.

The substrate 100 may include an isolation layer pattern 105 thereon. Accordingly, a portion of the substrate 100 on which the isolation layer pattern 105 is formed may be defined as a field region, a portion of the substrate 100 on which no isolation layer pattern is formed may be defined as an active region. The transistor may be formed in the active region. The substrate 100 may be a silicon substrate, a germanium substrate, a silicon-germanium substrate, a silicon-on-insulator (SOI) substrate, a germanium-on-insulator (GOI) substrate, etc. The isolation layer pattern 105 may include an oxide, e.g., silicon oxide.

A first insulating interlayer 170 formed on the substrate 100 may cover the transistor, and first and second contact plugs 181 and 183 may be formed through the first insulating interlayer 170 to contact top surfaces of the impurity region 160. First and second pads 191 and 193 may be formed on the first insulating interlayer 170 to contact top surfaces of the first and second contact plugs 181 and 183, respectively. A second insulating interlayer 200 formed on the first insulating interlayer 170 and may cover the first and second pads 191 and 193. A third contact plug 210 may be formed through the second insulating interlayer 200 to contact a top surface of the first pad 191.

The first and second insulating interlayers 170 and 200 may include an oxide, e.g., silicon oxide. The first and second pads 191 and 193 may include a conductive material, e.g., a metal. The first to third contact plugs 181, 183 and 210 may include a conductive material, e.g., a metal and/or polysilicon doped with impurities.

The lower electrode 225 may be formed on the second insulating interlayer 200 to contact a top surface of the third contact plug 210. The lower electrode 225 may include a conductive material, e.g., a metal such as tungsten (W), titanium (Ti), tantalum (Ta) and/or a metal nitride such as tungsten nitride (WN), titanium nitride (TiN), tantalum nitride (TaN). In example embodiments, the lower electrode 225 may extend in a first direction substantially parallel to a top surface of the substrate 100, and a plurality of lower electrodes 225 may be formed in a second direction substantially parallel to the top surface of the substrate 100 and substantially perpendicular to the first direction.

The first MTJ structure 401 may include a first pinning layer pattern 235, a first tunnel barrier layer pattern 245, a free layer pattern 255, a second tunnel barrier layer pattern 265, a capping layer pattern 275 and a second pinning layer pattern 310 sequentially stacked on the lower electrode 225.

The first pinning layer pattern 235 may contact the lower electrode 225 and has a first thickness, and the second pinning layer pattern 310 may have a second thickness thicker than the first thickness. The first and second pinning layer patterns 235 and 310 may have first and second magnetization directions, respectively. In example embodiments, the first and second magnetization directions may be substantially perpendicular to the top surface of the substrate 100 or substantially parallel to the top surface of the substrate 100. The first and second magnetization directions may be substantially opposite to each other. The first and second thicknesses may not be limited and can be changed easily according to the first MTJ structure 401. In example embodiments, a plurality of first pinning layer patterns 235 and a plurality of second pinning layer patterns 310 may be formed in the first and second directions.

The free layer pattern 255 may include a ferromagnetic material, e.g. iron (Fe), nickel (Ni), cobalt (Co), etc. In example embodiments, the free layer pattern 255 may have a third magnetization direction, which may be substantially perpendicular to the top surface of the substrate 100 or parallel to the top surface of the substrate 100. In one example embodiment, the third magnetization direction may be substantially the same as the first magnetization direction, and substantially opposite to the second magnetization direction. In example embodiments, a plurality of free layer patterns 255 may be formed in the first and second directions.

The first and second tunnel barrier layer patterns 245 and 265 may include a metal oxide, a metal nitride, a metal oxynitride, e.g., magnesium oxide (MgO) or aluminum oxide (AlO). In example embodiments, a plurality of first tunnel barrier layer patterns 245 and a plurality of second tunnel barrier layer patterns 265 may be formed in the first and second directions.

The capping layer pattern 275 may include a metal, e.g., tantalum (Ta). In example embodiments, a plurality of capping layer patterns 275 may be formed in the first and second directions.

A second spacer 295 may surround sidewalls of the first pinning layer pattern 235, the first tunnel barrier layer pattern 245, the free layer pattern 255, the second tunnel barrier layer pattern 265 and the capping layer pattern 275. The second spacer 295 may be formed on the second insulating interlayer 200 so as to also surround a sidewall of the lower electrode 225. The second pinning layer pattern 310 may contact top surfaces of the capping layer pattern 275 and the second spacer 295. The second spacer 295 may include an oxide and/or a nitride, e.g., aluminum oxide (AlO₂O₃), silicon oxide or silicon nitride.

A third insulating interlayer 300 may surround a sidewall of the second pinning layer pattern 310 and an outer sidewall of the second spacer 295. The third insulating interlayer 300 may include an oxide, e.g., silicon oxide.

The wiring 360 may be formed on the second pinning layer pattern 310 to contact a top surface thereof. The wiring 360 may include a metal layer pattern 350 and a barrier layer pattern 340 surrounding a bottom surface and a sidewall thereof. The metal layer pattern 350 may include, e.g., copper (Cu). The barrier layer pattern 340 may include a metal or a metal nitride, e.g., tantalum (Ta), tantalum nitride (TaN), titanium (Ti), titanium nitride (TiN). In example embodiments, a plurality of wirings 360 may be formed in the second direction, each of which may extend in the first direction.

A fourth insulating interlayer 330 on the third insulating interlayer 300 may surround a sidewall of the wiring 360, and an etch stop layer 320 may be formed between the third and fourth insulating interlayers 300 and 330. The fourth insulating interlayer 330 may include an oxide, e.g., silicon oxide, and the etch stop layer 320 may include a nitride, silicon nitride.

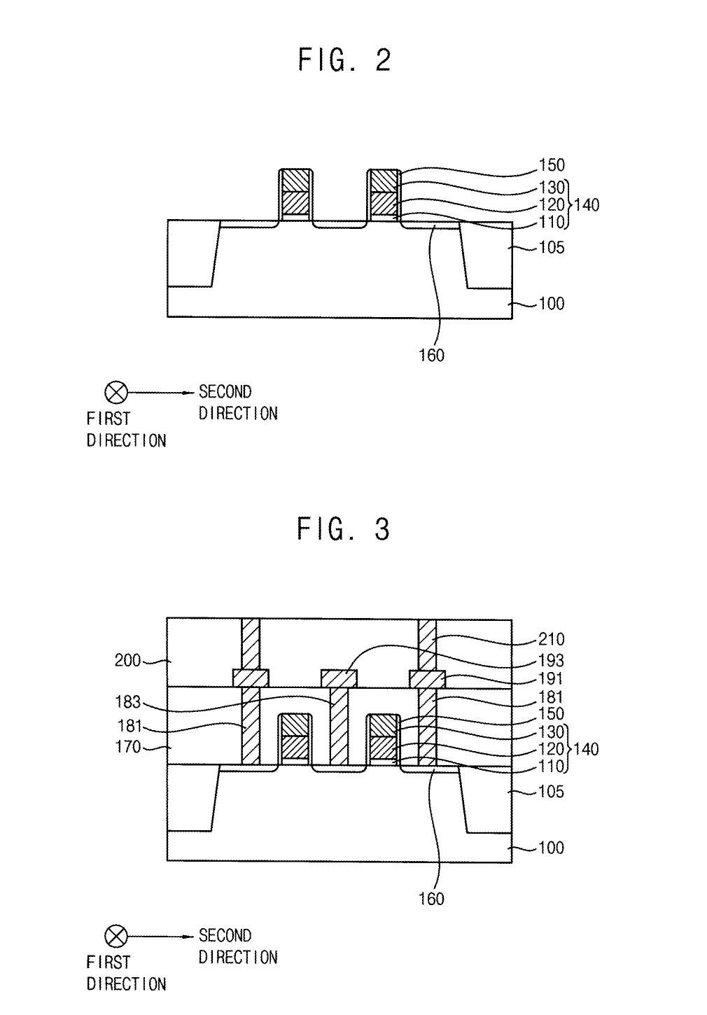

FIGS. 2 to 10 are cross-sectional views illustrating a method of manufacturing an MRAM device in accordance with example embodiments.

Referring to FIG. 2, an isolation layer pattern 105 may be formed at an upper portion of a substrate 100 to divide the substrate 100 into an active region and a field region, and a transistor including a gate structure 140 and an impurity region 160 may be formed in the active region.

The substrate 100 may be a silicon substrate, a germanium substrate, a silicon-germanium substrate, a silicon-on-insulator (SOI) substrate, a germanium-on-insulator (GOI) substrate, etc.

The isolation layer pattern 105 may be formed by forming a trench (not shown) at an upper portion of the substrate 100, forming an isolation layer on the substrate 100 to sufficiently fill the trench, and planarizing an upper portion of the isolation layer until a top surface of the substrate 100 may be exposed. Accordingly, a portion of the substrate 100 on which the isolation layer pattern 105 is formed may be defined as the field region, and a portion of the substrate 100 on which no isolation layer pattern is formed may be defined as the active region. The isolation layer may include an oxide, e.g., silicon oxide.

The transistor may be formed by forming the gate structure 140 on the substrate 100, forming a first spacer 150 on a sidewall of the gate structure 140, and forming the impurity region 160 at an upper portion of the substrate 100 adjacent to the gate structure 140 and the first spacer 150.

The gate structure 140 may be formed by sequentially forming a gate insulation layer, a gate electrode layer and a mask 130, and sequentially patterning the gate electrode layer and the gate insulation layer using the mask 130 as an etching mask. Accordingly, the gate structure 140 may be formed to include a gate insulation layer pattern 110, a gate electrode 120 and the mask 130 sequentially stacked on the substrate 100.

The first spacer 150 may be formed by forming a first spacer layer on the substrate 100 to cover the gate structure 140, and anisotropically etching the first spacer layer. The first spacer layer may be formed to include a nitride, e.g., silicon nitride.

The impurity region 160 may be formed by performing an ion implantation process on the substrate 300 to include, e.g., n-type impurities such as phosphorus, arsenic, etc., or p-type impurities such as boron, gallium, etc. The impurity region 160 may serve as source/drain regions of the transistor.

In some example embodiments, after the impurity region 160 may be formed, the gate structure 140 and the first spacer 150 may be formed to define the transistor.

Referring to FIG. 3, a first insulating interlayer 170 may be formed on the substrate 100 to cover the transistor, and first and second contact plugs 181 and 183 may be formed through the first insulating interlayer 170 to contact a top surface of the impurity region 160.

The first and second contact plugs 181 and 183 may be formed via the following steps. The first insulating interlayer 170 may be etched to form first contact holes (not shown) exposing top surfaces of the impurity region 160. A first conductive layer may be formed on the substrate 100 and the first insulating interlayer 170 to fill the first contact holes. An upper portion of the first conductive layer may be planarized until a top surface of the first insulating interlayer 170 may be exposed. The first conductive layer may be formed to include a metal and/or a polysilicon doped with impurities.

Thereafter, first and second pads 191 and 193 may be formed on the first insulating interlayer 170 to contact top surfaces of the first and second contact plugs 181 and 183, respectively, and a second insulating interlayer 200 may be formed on the first insulating interlayer 170 to cover the first and second pads 191 and 193. A third contact plug 210 may be formed through the second insulating interlayer 200 to contact a top surface of the first pad 191.

The first and second pads 191 and 193 may be formed by forming a second conductive layer on the first insulating interlayer 170, and patterning the second conductive layer. The second conductive layer may be formed to include, e.g., a metal.

The third contact plug 210 may be formed by the following steps. The second insulating interlayer 200 may be etched to form a second contact hole (not shown) exposing the top surface of the first pad 191. A third conductive layer may be formed on the first pad 191 and the second insulating interlayer 200 to fill the second contact hole. An upper portion of the third conductive layer may be planarized until a top surface of the second insulating interlayer 200 may be exposed. The third conductive layer maybe formed to include a metal and/or a polysilicon doped with impurities.

The first insulating interlayer 170 may be formed to include an oxide, e.g., silicon oxide, and the second insulating interlayer 200 may be formed to include a nitride, e.g., silicon nitride.

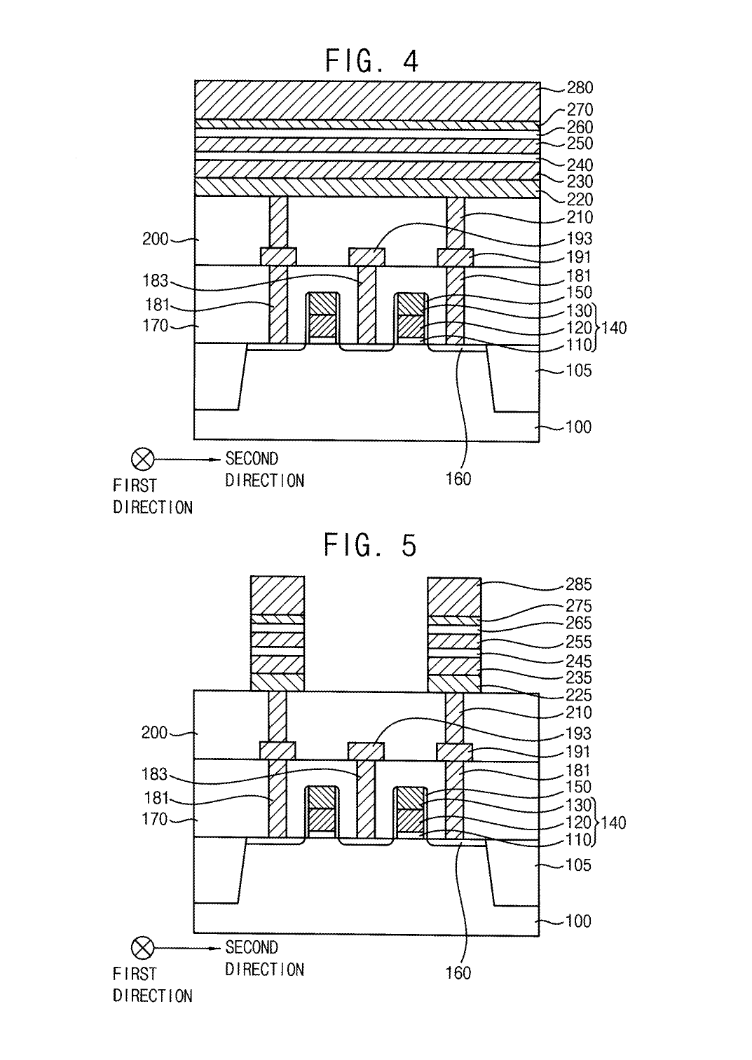

Referring to FIG. 4, a lower electrode layer 220, a first pinning layer 230, a first tunnel barrier layer 240, a free layer 250, a second tunnel barrier layer 260, a capping layer 270 and a hard mask layer 280 may be sequentially formed on the second insulating interlayer 200.

The lower electrode layer 220 may be formed to include a conductive material, e.g., a metal such as tungsten (W), titanium (Ti), tantalum (Ta) and/or a metal nitride such as, tungsten nitride (WN), titanium nitride (TiN), tantalum nitride (TaN).

The first pinning layer 230 may be formed to include a ferromagnetic material having a first crystal structure, and thus may have a first magnetization direction. In example embodiments, the first magnetization direction may be substantially perpendicular to the top surface of the substrate 100 or substantially parallel to the top surface of the substrate 100. The first pinning layer 230 may have a first thickness.

The free layer 250 may be formed to include a ferromagnetic material having a third magnetization direction, e.g., iron (Fe), nickel (Ni), cobalt (Co). In example embodiments, the third magnetization direction may be substantially perpendicular to the top surface of the substrate 100 or substantially parallel to the top surface of the substrate 100. In one example embodiment, the third magnetization may be substantially the same as the first magnetization direction.

The first and second tunnel barrier layers 240 and 260 may be formed to include a metal oxide, a metal nitride or a metal oxynitride, e.g., magnesium oxide (MgO) or aluminum oxide (AlO).

The capping layer 270 may be formed to include, e.g., a metal such as tantalum (Ta).

The hard mask layer 280 may be formed to include, e.g., a metal and/or a metal nitride.

Referring to FIG. 5, the hard mask layer 280 may be etched to form a hard mask 285, and the capping layer 270, the second tunnel barrier layer 260, the free layer 250, the first tunnel barrier layer 240, the first pinning layer 230 and the lower electrode layer 220 may be sequentially patterned using the hard mask as an etching mask. Accordingly, a lower electrode 225, a first pinning layer pattern 235, a first tunnel barrier layer pattern 245, a free layer pattern 255, a second tunnel barrier layer pattern 265, and a capping layer pattern 275, sequentially stacked on the second insulating interlayer 200 and the third contact plug 210, may be formed, and the lower electrode 225 may contact a top surface of the third contact plug 210.

In example embodiments, the patterning process may be performed by a physical etching process such as a plasma reaction etching process or an ion sputtering process. The plasma reaction etching process may be performed using an etching gas including, e.g., HF and/or NH₃, and a reaction gas including, e.g., oxygen.

In example embodiments, a plurality of hard masks 285 may be formed in a first direction substantially parallel to the top surface of the substrate 100, and in a second direction substantially parallel to the top surface of the substrate 100 and substantially perpendicular to the first direction. Thus, a plurality of lower electrodes 225, a plurality of first pinning layer patterns 235, a plurality of first tunnel barrier layer patterns 245, a plurality of free layer patterns 255, a plurality of second tunnel barrier layer patterns 265 and a plurality of capping layer patterns 275 may be formed in both the first and second directions.

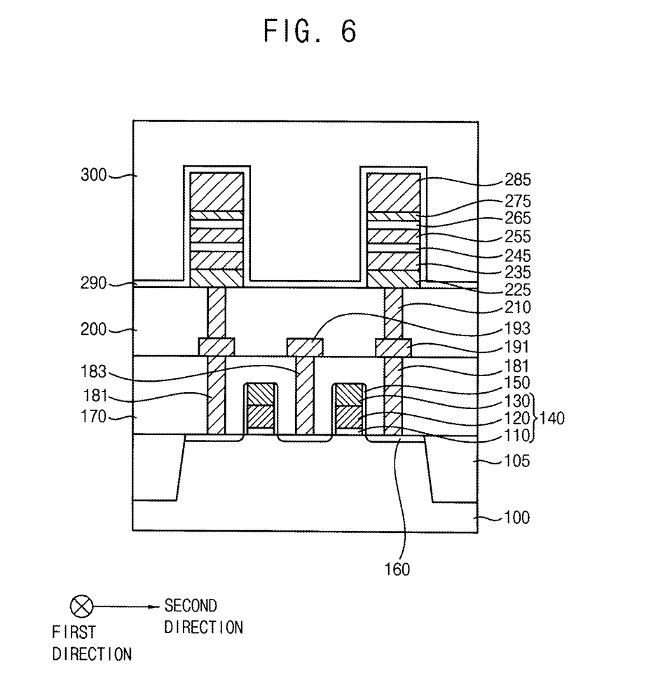

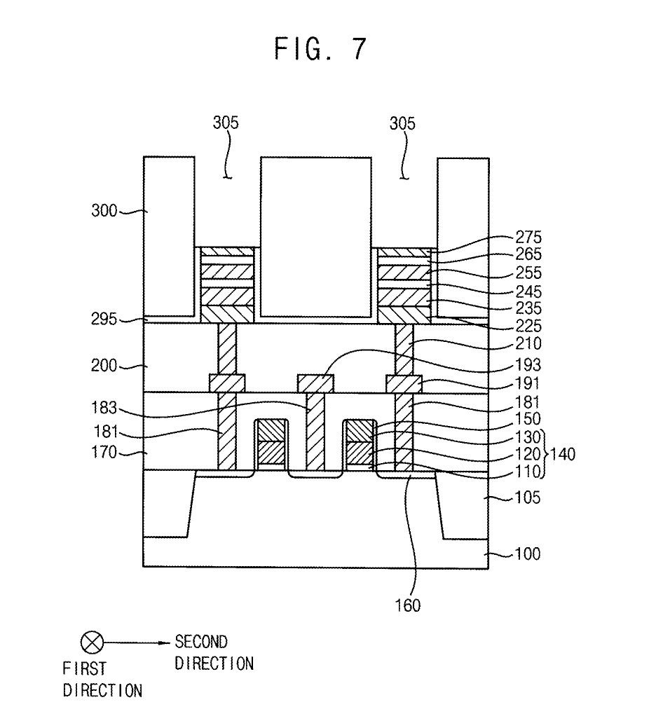

Referring to FIG. 6, a second spacer layer 290 and a third insulating interlayer 300 may be sequentially formed on the second insulating interlayer 200 to cover the lower electrode 225, the first pinning layer pattern 235, the first tunnel barrier layer pattern 245, the free layer pattern 255, the second tunnel barrier layer pattern 265, the capping layer pattern 275 and the hard mask 285.

In one example embodiment, the third insulating interlayer 300 may have a top surface substantially higher than a top surface of the second spacer layer 290 on the hard mask 285.

The second spacer layer 290 may include an oxide and/or a nitride, e.g., aluminum oxide (Al₂O₃), silicon oxide or silicon nitride. The third insulating interlayer 300 may include an oxide, e.g., silicon oxide.

Referring to FIG. 7, the third insulating interlayer 300, the second spacer layer 290 and the hard mask 285 may be etched to form at least a first recess 305. By the etching process, while the third insulating interlayer 300 and the second spacer layer 290 may be partially removed, the hard mask 285 may be substantially or entirely removed. Accordingly, a top surface of the capping layer pattern 275 may be exposed, and a second spacer 295 may be formed to surround sidewalls of the lower electrode 225, the first pinning layer pattern 235, the first tunnel barrier layer pattern 245, the free layer pattern 255, the second tunnel barrier layer pattern 265 and the capping layer pattern 275.

The first recess 305 may be formed by forming an etching mask (not shown) on the third insulating interlayer 300, and performing an anisotropic etching process using the etching mask. In example embodiments, a plurality of recesses 305 may be formed in the first and second directions.

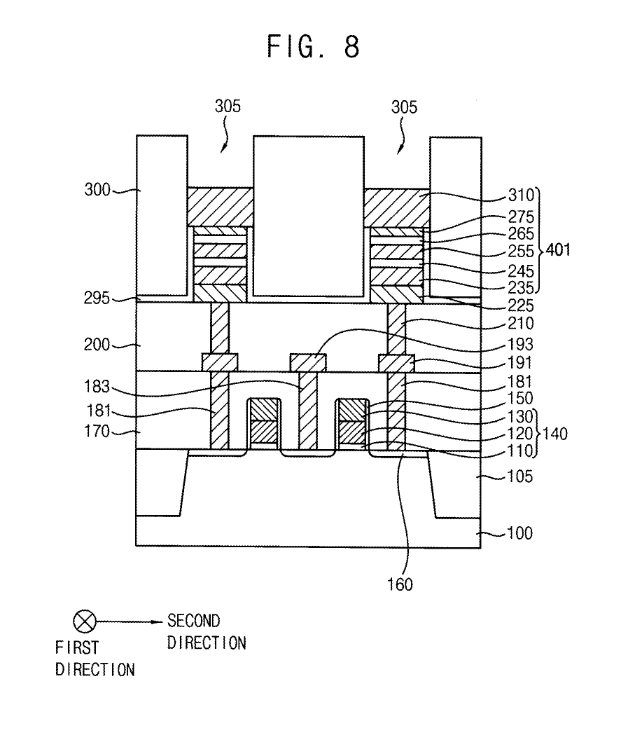

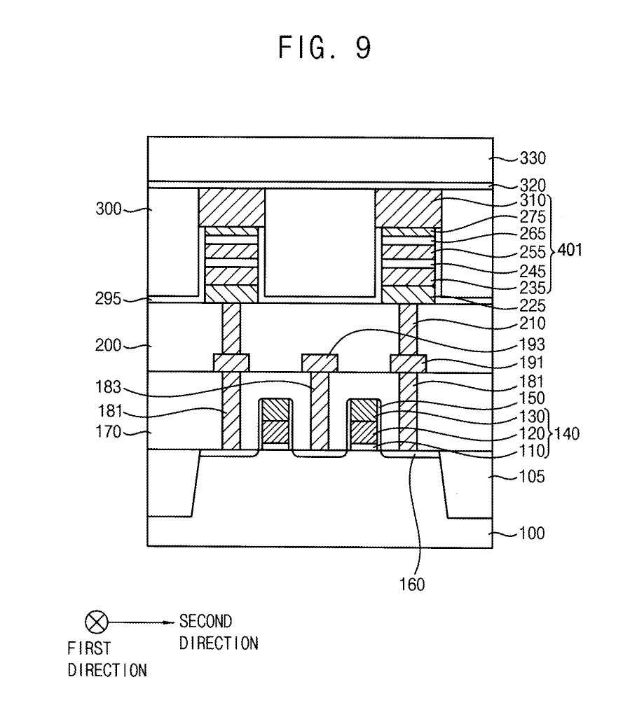

Referring to FIG. 8, a second pinning layer pattern 310 may be formed to fill at least a portion of the first recess 305. Accordingly, a plurality of second pinning layer patterns 310 may be formed in the first and second directions, each of which may contact the top surface of the capping layer pattern 275. The second pinning layer pattern 310, together with the first pinning layer pattern 235, the first tunnel barrier layer pattern 245, the free layer pattern 255, the second tunnel barrier layer pattern 265 and the capping layer pattern 275, may be defined as a first MTJ structure 401.

In example embodiments, the second pinning layer pattern 310 may be formed by a damascene process. That is, a second pinning layer may be formed on the capping layer pattern 275, the second spacer 295 and the third insulating interlayer 300 to substantially fill the first recess 305, and an upper portion of the second pinning layer may be removed by an etch back process to form the second pinning layer pattern 310. Accordingly, in some example embodiments, the second pinning layer pattern 310 may be formed to partially fill the first recess 305 as shown in FIG. 8. In other example embodiments, the second pinning layer pattern 310 may be formed to substantially fill the first recess 305.

The second pinning layer pattern 310 may be formed to include a ferromagnetic material having a second crystal structure that is different from the first crystal structure, and thus may have a second magnetization direction that is substantially opposite to the first magnetization direction. In example embodiments, the second magnetization direction may be substantially perpendicular to the top surface of the substrate 100 or substantially parallel to the top surface of the substrate 100.

The second pinning layer pattern 310 may have a second thickness that is thicker than the first thickness. The first and second thicknesses may not be limited and may be changed easily according to the first MTJ structure 401.

Referring to FIG. 9, an upper portion of the third insulating interlayer 300 may be planarized until a top surface of the third insulating interlayer 300 may be substantially coplanar with the top surface of the second pinning layer pattern 310. An etch stop layer 320 and a fourth insulating interlayer 330 may be sequentially formed on the planarized third insulating interlayer 300 and the second pinning layer pattern 310. The etch stop layer 320 may include a nitride, e.g., silicon nitride, and the fourth insulating interlayer 330 may include an oxide, e.g., silicon oxide.

When the second pinning layer pattern 310 substantially fills the first recess 305, the planarizing process may be omitted.

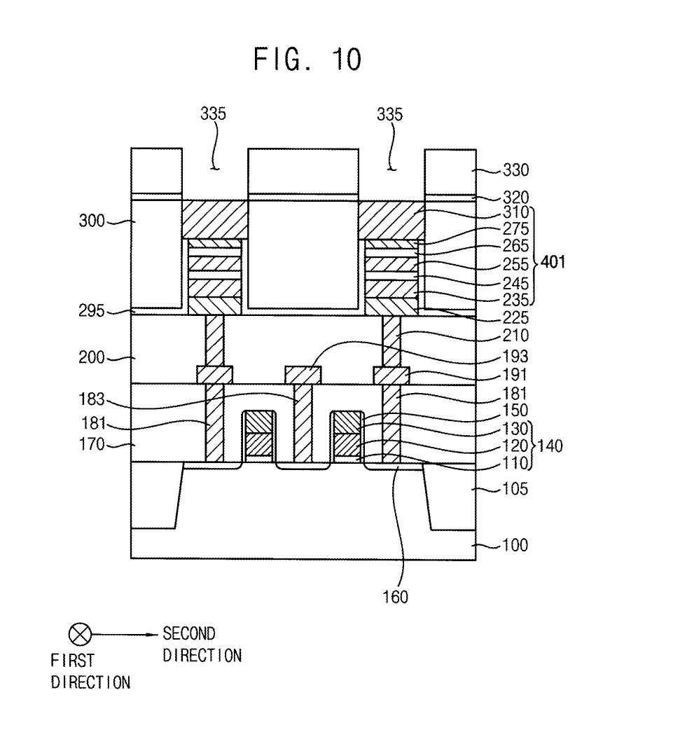

Referring to FIG. 10, the fourth insulating interlayer 330 and the etch stop layer 320 may be partially removed to form at least a first opening 335 exposing the top surface of the second pinning layer pattern 310.

The first opening 335 may be formed by forming an etching mask (not shown) on the fourth insulating interlayer 330, etching the fourth insulating interlayer 330 using the etching mask to expose a portion of the etch stop layer 320, and removing the exposed portion of the etch stop layer 320. In example embodiments, a plurality of first openings 335 may be formed in the second direction, each of which may extend in the first direction perpendicularly to the second direction.

Referring to FIG. 1 again, a wiring 360 may be formed on the second pinning layer pattern 310 to fill the first opening 335.

The wiring 360 may be formed by the following steps. A barrier layer may be formed on the exposed top surface of the second pinning layer pattern 310, a sidewall of the first opening 335 and the fourth insulating interlayer 330. A metal layer may be formed on the barrier layer to fill a remaining portion of the first opening 335. Upper portions of the barrier layer and of the metal layer may be planarized until a top surface of the fourth insulating interlayer 330 may be exposed. Accordingly, the wiring 360 may be formed to include a metal layer pattern 350 and a barrier layer pattern 340 that surrounds a bottom surface and a sidewall of the metal layer pattern 350. The metal layer may include, e.g., copper (Cu). The barrier layer may include a metal or a metal nitride, e.g., tantalum (Ta), tantalum nitride (TaN), titanium (Ti), titanium nitride (TiN).

In example embodiments, a plurality of wirings 360 may be formed in the second direction, and each of which may also extend in the first direction.

As described above, when the first MTJ 401 structure is formed, the first pinning layer pattern 235 having a relatively small thickness may be formed by a physical etching process together with the lower electrode 225, the first tunnel barrier layer pattern 245, the free layer pattern 255, the second tunnel barrier layer pattern 265, the capping layer pattern 275, and the second pinning layer pattern 310 having a relatively larger thickness may be formed by a damascene process. That is, the second pinning layer pattern 310 may not be formed together with the patterns of the first MTJ structure 401 thereunder by a physical etching process. Therefore, the attachment of a magnetic material onto a sidewall of the first MTJ structure 401 may be reduced, or alternatively prevented.

Moreover, the first and second pinning layer patterns 235 and 310, which may have magnetization directions that are substantially opposite to each other, may be formed both beneath and above the free layer pattern 255, respectively. As a result, an upper electrode may not be formed on the free layer pattern 255, and the deterioration of magnetic characteristics of the MRAM device may be reduced, or alternatively prevented.

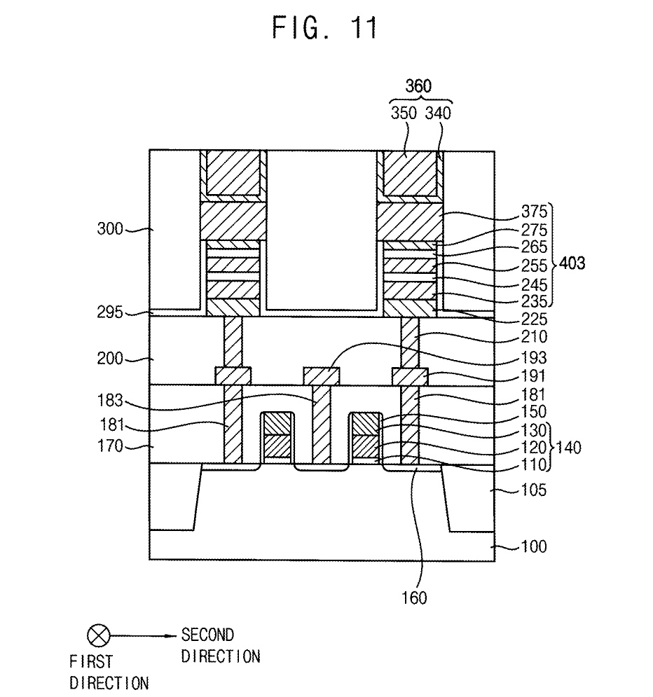

FIG. 11 is a cross-sectional view illustrating an MRAM device in accordance with example embodiments. The MRAM device of FIG. 11 may be substantially the same as or similar to the device illustrated with reference to FIG. 1, except for having a third pinning layer pattern 375. Thus, like reference numerals refer to like elements, and detailed explanations thereabout may be omitted herein.

Referring to FIG. 11, the MRAM device may include a transistor containing a gate structure 140 and an impurity region 160, a lower electrode 225, a second MTJ structure 403 and a wiring 360. The MRAM device may further include first and second spacers 150 and 295, first to third contact plugs 181, 183 and 210, first and second pads 191 and 193 and first to third insulating interlayers 170, 200 and 300.

The second MTJ structure 403 may include a first pinning layer pattern 235, a first tunnel barrier layer pattern 245, a free layer pattern 255, a second tunnel barrier layer pattern 265, a capping layer pattern 275 and the third pinning layer pattern 375 sequentially stacked on the lower electrode 225.

The first and third pinning layer patterns 235 and 375 may include ferromagnetic materials having crystal structures different from each other, and thus may have magnetization directions that may be substantially opposite to each other. In example embodiments, the first and third pinning layer patterns 235 and 375 may have first and fourth magnetization directions, respectively, which may be substantially perpendicular to the top surface of the substrate 100 or substantially parallel to the top surface of the substrate 100. The first and fourth magnetization directions may be substantially opposite to each other. The first pinning layer pattern 235 may contact the lower electrode 235 and have a first thickness, and the third pinning layer pattern 375 may have a third thickness that is larger than the first thickness. The first and third thicknesses may not be limited and may be changed easily according to the second MTJ structure 403.

In example embodiments, a plurality of first pinning layer patterns 235 may be formed in a first direction that is substantially parallel to the top surface of the substrate 100 and in a second direction that is substantially parallel to the top surface of the substrate 100 and substantially perpendicular to the first direction. A plurality of third pinning layer patterns 375 may be formed in the second direction, each of which may extend in the first direction.

A plurality of free layer patterns 255 may be formed in the first and second directions. In example embodiments, the free layer pattern 255 may have a second magnetization direction, which may be substantially perpendicular to the top surface of the substrate 100 or substantially parallel to the top surface of the substrate 100. In one example embodiment, the second magnetization direction may be substantially the same as the magnetization direction of the first pinning layer pattern 235 and substantially opposite to the magnetization direction of the third pinning layer pattern 375.

In example embodiments, a plurality of first tunnel barrier layer patterns 245, a plurality of second barrier layer patterns 265 and a plurality of capping layer patterns 275 may be formed in the first and second directions.

The second spacer 295 may surround the sidewalls of the first pinning layer pattern 235, the first tunnel barrier layer pattern 245, the free layer pattern 255, the second tunnel barrier layer patterns 265 and the capping layer pattern 275. The second spacer 295 may be formed on the second insulating interlayer 295 so as to also surround the sidewall of the lower electrode 225. The third pinning layer pattern 375 may contact the top surfaces of the capping layer pattern 275 and the second spacer 295.

The third insulating interlayer 300 may surround a sidewall of the third pinning layer pattern 375, the sidewall of the wiring 360 and an outer sidewall of the second spacer 295.

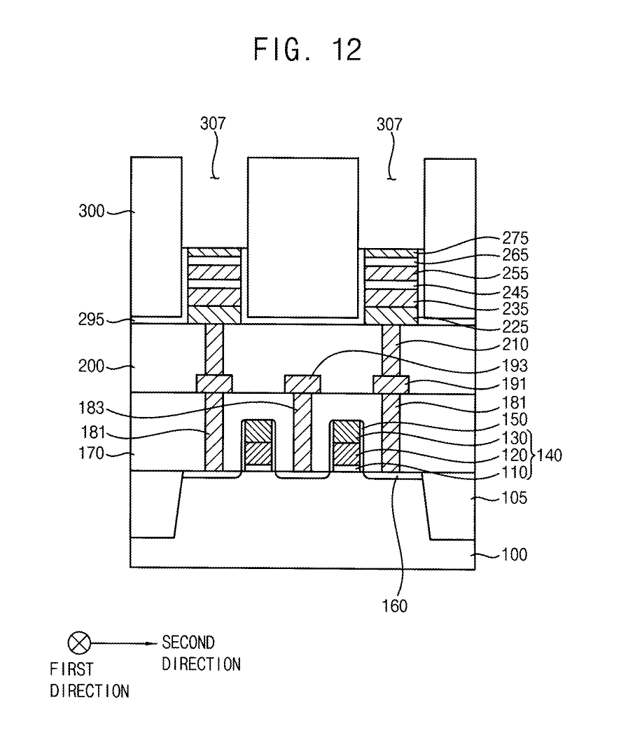

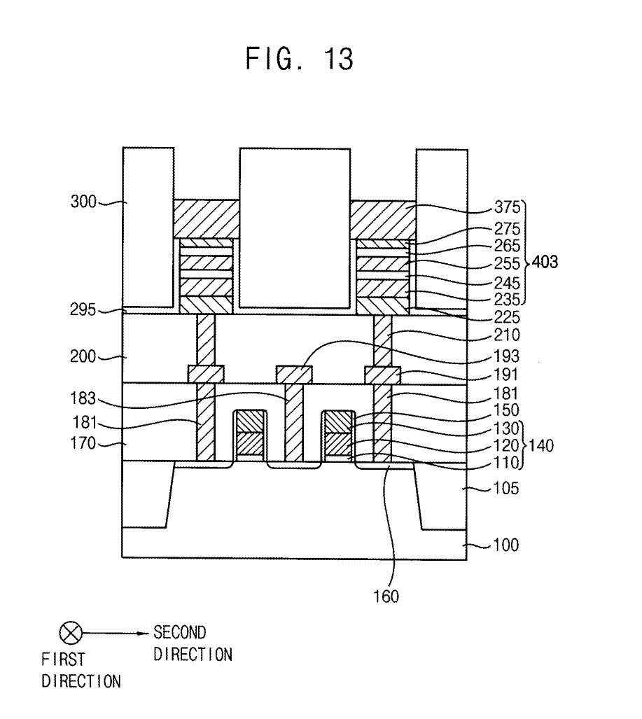

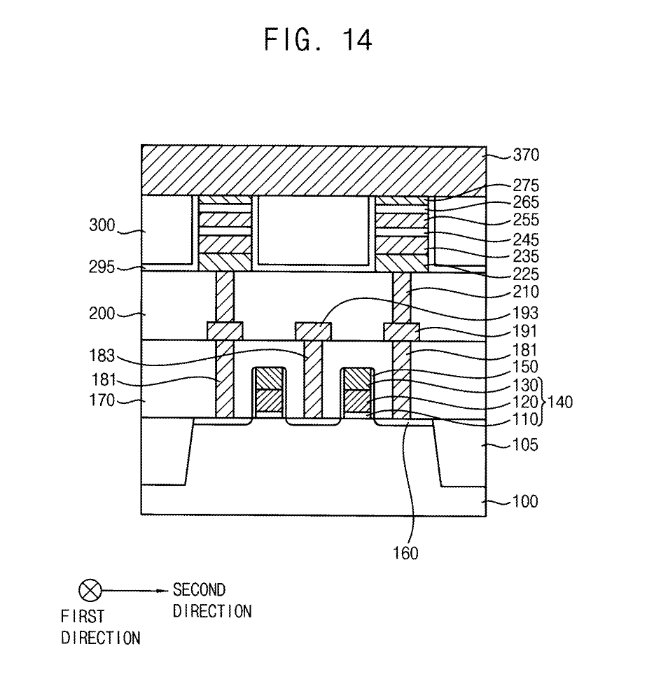

FIGS. 12 to 13 are cross-sectional views illustrating a method of manufacturing an MRAM device in accordance with example embodiments. The method may include processes substantially the same as or similar to those illustrated with reference to FIGS. 2 to 10 except for forming a third pinning layer pattern 375. Thus, like reference numerals refer to like elements, and detailed explanations thereabout may be omitted herein.

First, processes substantially the same as or similar to those illustrated with reference to FIGS. 2 to 6 may be performed. Thus, the transistor including the gate structure 140 and the impurity region 160, the first to third contact plugs 181, 183 and 210, the first and second pads 191 and 193, and the first and second insulating interlayers 170 and 200 may be formed. In addition, the lower electrode 225, the first pinning layer pattern 235, the first and second tunnel barrier layer patterns 245 and 265, the free layer pattern 255, the capping layer pattern 275 and the hard mask 285 may be formed, and the third insulating interlayer 300 may be formed to cover the lower electrode 225, the first pinning layer pattern 235, the first and second tunnel barrier layer patterns 245 and 265, the free layer pattern 255, the capping layer pattern 275 and the hard mask 285.

Referring to FIG. 12, the third insulating interlayer 300, the second spacer layer 290 and the hard mask 285 may be etched to form at least a second recess 307. By the etching process, the third insulating interlayer 300 and the second spacer layer 290 may be partially removed, and the hard mask 285 may be sufficiently removed. Accordingly, a top surface of the capping layer pattern 275 may be exposed, and a second spacer 295 may be formed to surround sidewalls of the lower electrode 225, the first pinning layer pattern 235, the first tunnel barrier layer pattern 245, the free layer pattern 255, the second tunnel barrier layer pattern 265 and the capping layer pattern 275. In example embodiments, the second recess 307 may extend in a first direction that is substantially parallel to the top surface of the substrate 100, and a plurality of second recesses 307 may be formed in a second direction that is substantially parallel to the top surface of the substrate 100 and substantially perpendicular to the first direction.

Referring to FIG. 13, the third pinning layer pattern 375 may be formed to fill at least a portion of the second recess 307. Accordingly, the third pinning layer pattern 375 may contact the top surfaces of the capping layer pattern 275 and the second spacer 295. In example embodiments, a plurality of third pinning layer patterns 375 may be formed in the second direction, each of which may extend in the first direction. The third pinning layer pattern 375, together with the first pinning layer pattern 235, the first tunnel barrier layer pattern 245, the free layer pattern 255, the second barrier layer pattern 265 and the capping layer pattern 275, may be defined as a second MTJ structure 403.

In example embodiments, the third pinning layer pattern 375 may be formed by a damascene process. That is, a third pinning layer may be formed on the second spacer 295 and the third insulating interlayer 300 to fill the second recess 307, and an upper portion of the third pinning layer may be removed by an etch back process.

Alternatively, the second recess 307 may be only partially filled by a damascene process to form the third pinning layer pattern 375, and in this case, the etch back process may be omitted.

The third pinning layer pattern 375 may be formed to include a ferromagnetic material having a third crystal structure substantially different from the crystal structure of the first pinning layer pattern 235. Accordingly, the third pinning layer pattern 375 may have a fourth magnetization direction that is substantially opposite to the magnetization direction of the first pinning layer pattern 235. In example embodiments, the fourth magnetization direction may be substantially perpendicular to the top surface of the substrate 100 or substantially parallel to the top surface of the substrate 100.

The third pinning layer pattern 375 may have a third thickness that is greater than the first thickness of the first pinning layer pattern 235. The first and third thicknesses may not be limited but be changed easily according the second MTJ structure 403.

Referring to FIG. 11 again, processes substantially the same as or similar to those illustrated with reference to FIG. 1 may be performed to form the wiring 360 filling a remaining portion of the second recess 307. Accordingly, the wiring 360 may contact a top surface of the third pinning layer pattern 375. In example embodiments, a plurality of wirings 360 may be formed in the second direction, each of which may extend in the first direction. The wiring 360 may be formed to include a metal layer pattern 350 and a barrier layer pattern 340 surrounding a bottom surface and a sidewall of the metal layer pattern 350.

As described above, when the second MTJ 403 structure is formed, the first pinning layer pattern 235 having a relatively small thickness may be formed by a physical etching process together with the lower electrode 225, the first tunnel barrier layer pattern 245, the free layer pattern 255, the second tunnel barrier layer pattern 265 and the capping layer pattern 275, and the third pinning layer pattern 375 having a relatively larger thickness may be formed by a damascene process.

Particularly, the third pinning layer pattern 375 and the wiring 360 may be formed in the same recess to fill lower and upper portions thereof, respectively, and thus the present inventive concepts may have the advantage of simplification.

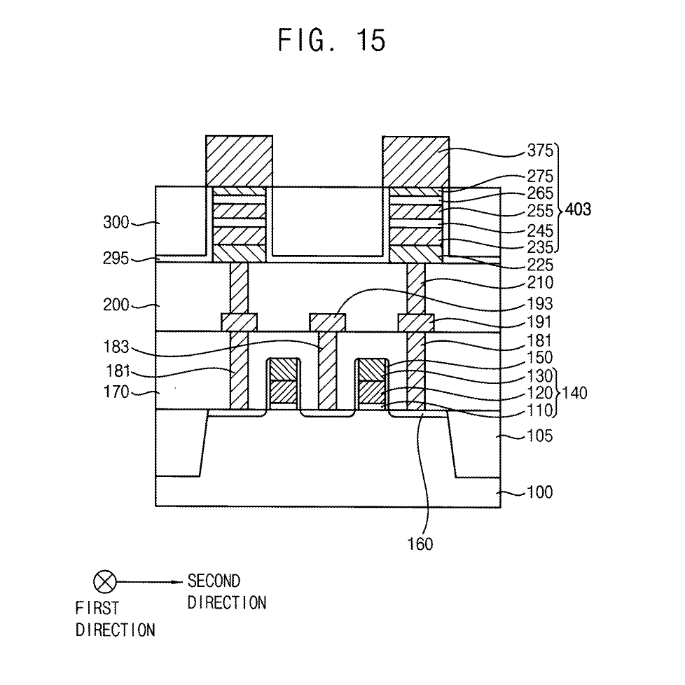

FIGS. 14 to 16 are cross-sectional views illustrating a method of manufacturing an MRAM device in accordance with example embodiments. The method may include processes substantially the same as or similar to those illustrated with reference to FIGS. 2 to 10 except for forming a third pinning layer pattern 375. Thus, like reference numerals refer to like elements, and detailed explanations thereabout may be omitted herein.

First, processes substantially the same as or similar to those illustrated with reference to FIGS. 2 to 6 may be performed. Thus, the transistor including the gate structure 140 and the impurity region 160, the first to third contact plugs 181, 183 and 210, the first and second pads 191 and 193 and the first and second insulating interlayers 170 and 200 may be formed. In addition, the lower electrode 225, the first pinning layer pattern 235, the first and second tunnel barrier layer patterns 245 and 265, the free layer pattern 255, the capping layer pattern 275 and the hard mask 285 may be formed, and the third insulating interlayer 300 may be formed to cover the lower electrode 225, the first pinning layer pattern 235, the first and second tunnel barrier layer patterns 245 and 265, the free layer pattern 255, the capping layer pattern 275 and the hard mask 285.

Referring to FIG. 14, upper portions of the second spacer layer 295 and third insulating interlayer 300 may be planarized until a top surface of the capping layer pattern 275 may be exposed. By the planarizing process, the hard mask 285 may be substantially removed, and a second spacer 295 may be formed to surround the sidewalls of the lower electrode 225, the first pinning layer pattern 235, the first tunnel barrier layer pattern 245, the free layer pattern 255, the second tunnel barrier layer pattern 265 and the capping layer pattern 275.

Thereafter, a third pinning layer 370 may be formed on the planarized third insulating interlayer 300, the second spacer 295 and the capping layer pattern 275.

The third pinning layer 370 may be formed to include a ferromagnetic material having a third crystal structure that is substantially different from the crystal structure of the first pinning layer pattern 235. Accordingly, the third pinning layer 370 may have a fourth magnetization direction that is substantially opposite to the first magnetization direction. In example embodiments, the fourth magnetization direction may be substantially perpendicular to the top surface of the substrate 100 or substantially parallel to the top surface of the substrate 100.

The third pinning layer 370 may have a third thickness that is larger than the thickness of the first pinning layer pattern 235. The first and third thicknesses may not be limited but be changed easily according to the second MTJ structure 403.

Referring to FIG. 15, the third pinning layer 370 may be patterned to form a third pinning layer pattern 375 contacting the top surface of the capping layer pattern 275. By the patterning process, the third pinning layer pattern 375 may extend in a first direction that is substantially parallel to the top surface of the substrate, and a plurality of third pinning layer patterns 375 may be formed in a second direction that is substantially parallel to the top surface of the substrate 100 and substantially perpendicular to the first direction.

In example embodiments, the patterning process may be performed by a physical etching process such as a plasma reaction etching process or an ion sputtering process. The plasma reaction etching process may be performed using an etching gas including, e.g., HF and/or NH₃, and a reaction gas including, e.g., oxygen.

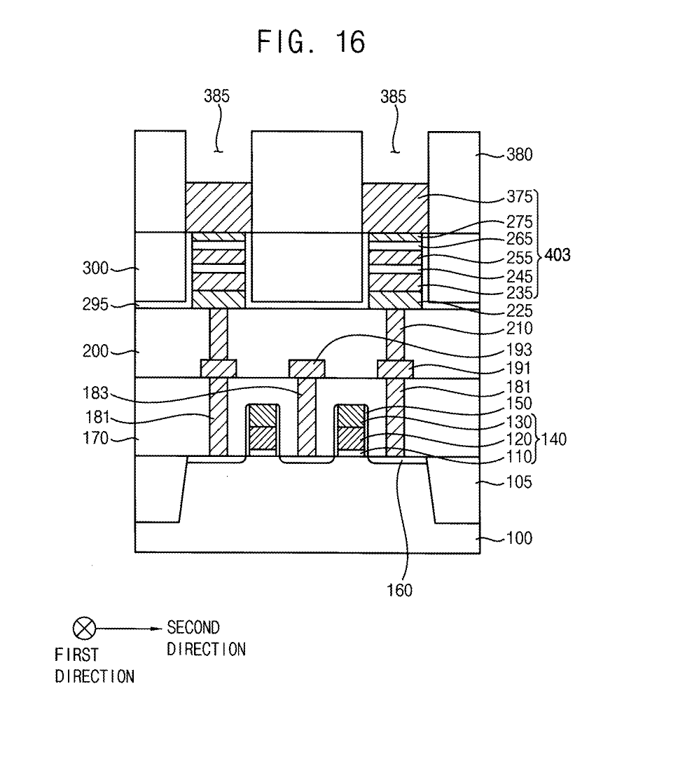

Referring to FIG. 16, a fifth insulating interlayer 380 may be formed on the third insulating interlayer 300 and the third pinning layer pattern 375 to sufficiently cover the third pinning layer pattern 375, and the fifth insulating interlayer 380 may be etched to form at least a second opening 385 exposing a top surface of the third pinning layer pattern 375. By the etching process, a plurality of second openings 385 may be formed in the second direction, each of which may extend in the first direction.

The fifth insulating interlayer 380 may be formed to include a material that is substantially the same as the material of the third insulating interlayer 300. That is, the fifth insulating interlayer 380 may be formed to include an oxide, e.g., silicon oxide, and thus may be merged to the third insulating interlayer 300. Thus, hereinafter, the merged layer structure may be referred to simply as the third insulating interlayer 300.

Thereafter, processes substantially the same as or similar to those illustrated with reference to FIG. 1 may be performed. That is, the wiring 360 contacting the top surface of the third pinning layer pattern 375 and filling the second opening 385 may be formed. As a result, the MRAM device may be manufactured as shown in FIG. 11.

As described above, after the lower electrode 225, the first pinning layer pattern 235, the first tunnel barrier layer pattern 245, the free layer pattern 255, the second tunnel barrier layer pattern 265 and the capping layer pattern 275 may be formed by a first physical etching process, the third pinning layer pattern 375 may be formed by a second physical etching process to form the second MTJ structure 403. That is, the first and third pinning layer patterns 235 and 375 may be formed by independent physical etching processes, respectively, and thus a height of the layers, which may be patterned at each physical etching process, may be minimized. As a result, the attachment of a magnetic material onto a sidewall of the second MTJ structure 403 may be reduced, or alternatively prevented, and thus the MRAM device may not be electrically short.

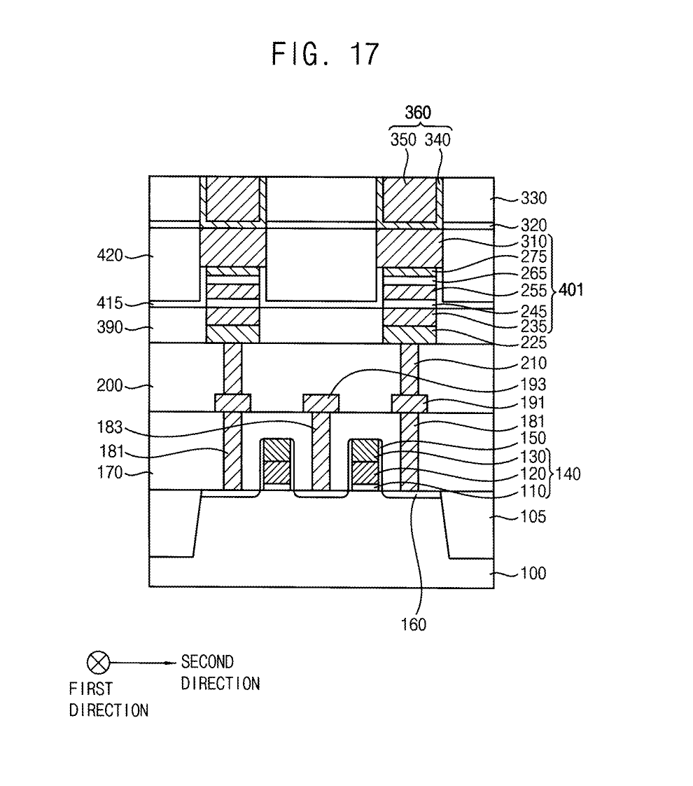

FIG. 17 is a cross-sectional view illustrating an MRAM device in accordance with example embodiments. The MRAM device of FIG. 17 may be substantially the same as or similar to the device illustrated with reference to FIG. 1 except for sixth and seventh insulating interlayers 390 and 420 and a third spacer 415. Thus, like reference numerals refer to like elements, and detailed explanations thereabout may be omitted herein.

Referring to FIG. 17, the MRAM device may include the transistor containing a gate structure 140 and an impurity region 160, a lower electrode 225, a first MTJ structure 401 and a wiring 360. The MRAM device may include a first spacer 150, first to third contact plugs 181, 183 and 210, first and second pads 191 and 193, first, second and fourth insulating interlayers 170, 200 and 330, and an etch stop layer 320. The MRAM device may further include the sixth and seventh insulating interlayers 390 and 420 and the third spacer 415.

The first MTJ structure 401 may include a first pinning layer pattern 235, a first tunnel barrier layer pattern 245, a free layer pattern 255, a second tunnel barrier layer pattern 265, a capping layer pattern 275 and a second pinning layer pattern 310 sequentially stacked on the lower electrode 225.

The sixth insulating interlayer 390 may be formed on the second insulating interlayer 200 to surround sidewalls of the lower electrode 225 and the first pinning layer pattern 235. The sixth insulating interlayer 390 may include an oxide, e.g., silicon oxide.

The third spacer 415 may be formed on the sixth insulating interlayer 390 to surround sidewalls of the first tunnel barrier layer pattern 245, the free layer pattern 255, the second tunnel barrier layer pattern 265 and the capping layer pattern 275. The second pinning layer pattern 310 may contact a top surface of the capping layer pattern 275 and a top surface of the third spacer 415. The third spacer 415 may include a nitride, e.g., silicon nitride.

The seventh insulating interlayer 420 may surround a sidewall of the second pinning layer pattern 310 and an outer sidewall of the third spacer 415. The seventh insulating interlayer 420 may include an oxide, e.g., silicon oxide.

The wiring 360 may be formed on the second pinning layer pattern 310 to contact a top surface thereof, and the fourth insulating interlayer 330 may surround a sidewall of the wiring 360. The fourth insulating interlayer 330 may be formed on the seventh insulating interlayer 420, and the etch stop layer 320 may be formed between the seventh and fourth insulating interlayers 420 and 330.

FIGS. 18 to 21 are cross-sectional views illustrating a method of manufacturing an MRAM device in accordance with example embodiments. The method may include processes substantially the same as or similar to those illustrated with reference to FIGS. 2 to 10 except for forming sixth and seventh insulating interlayers 390 and 420 and forming a third spacer 415. Thus, like reference numerals refer to like elements, and detailed explanations thereabout may be omitted herein.

First, processes substantially the same as or similar to those illustrated with reference to FIGS. 2 and 3 may be performed. Thus, the transistor including the gate structure 140 and the impurity region 160, the first to third contact plugs 181, 183 and 210, the first and second pads 191 and 193 and the first and second insulating interlayers 170 and 200 may be formed.

Referring to FIG. 18, processes substantially the same as or similar to those illustrated with reference to FIG. 4 may be performed. Thus, the lower electrode 235 and the first pinning layer pattern 235 may be formed. That is, the lower electrode 235 and the first pinning layer pattern 235 may be formed by sequentially forming the lower electrode layer 220 and the first pinning layer 230 on the second insulating interlayer 200 and the third contact plug 210, and patterning the lower electrode layer 220 and the first pinning layer 230. A plurality of lower electrodes 225 and a plurality of first pinning layer patterns 235 may be formed in a first direction that is substantially parallel to the top surface of the substrate 100 and a second direction that is parallel to the top surface of the top surface of the substrate 100 and substantially perpendicular to the first direction. The lower electrode 225 may contact the top surface of the third contact plug 210.

In example embodiments, the patterning process may be performed by a physical etching process such as a plasma reaction etching process or an ion sputtering process. The plasma reaction etching process may be performed using an etching gas including, e.g., HF and/or NH₃, and a reaction gas including, e.g., oxygen.

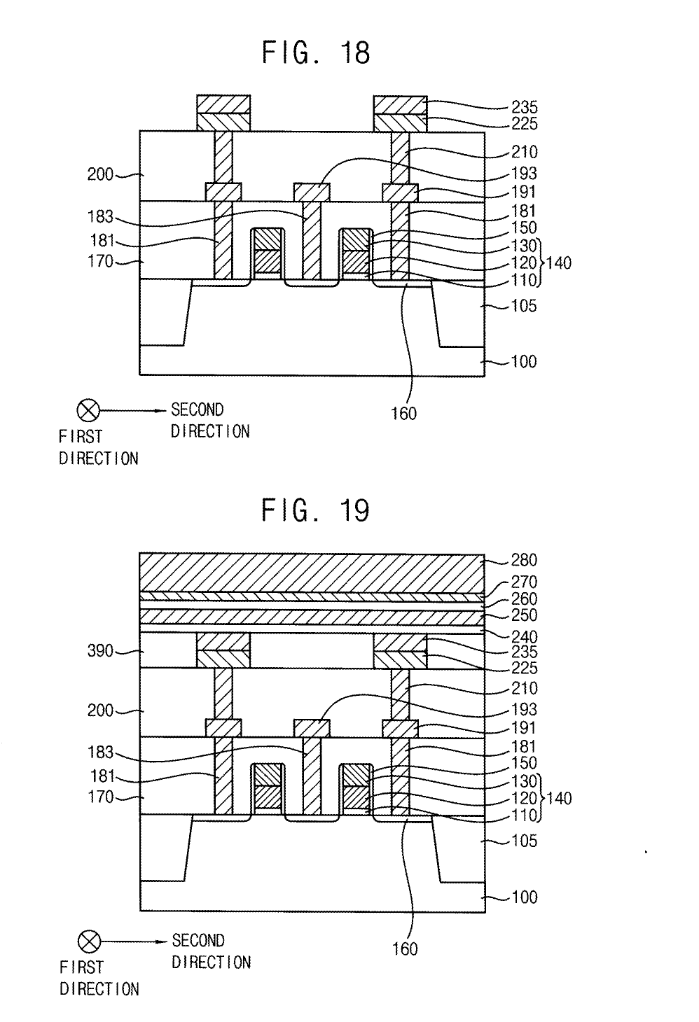

Referring to FIG. 19, a sixth insulating interlayer 390 may be formed on the second insulating interlayer 200 to sufficiently cover the lower electrode 225 and the first pinning layer pattern 235, and an upper portion of the sixth insulating interlayer 390 may be planarized until the top surface of the first pinning layer pattern 235 may be exposed. The tunnel barrier layer 240, the free layer 250, the second tunnel barrier layer 260, the capping layer 270 and the hard mask layer 280 may be sequentially formed on the planarized sixth insulating interlayer 390 and the first pinning layer pattern 235.

By the planarizing process, the sixth insulating interlayer 390 may surround sidewalls of the lower electrode 225 and the first pinning layer pattern 235. The sixth insulating interlayer 390 may be formed to include an oxide, e.g., silicon oxide.

A tunnel barrier layer 240, a free layer 250, a second tunnel barrier layer 260, a capping layer 270 and a hard mask layer 280 may be formed by processes substantially the same as or similar to those illustrated with reference to FIG. 4.

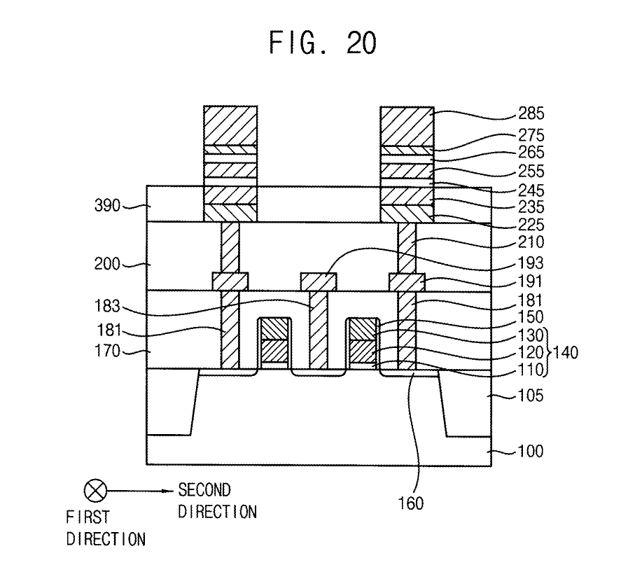

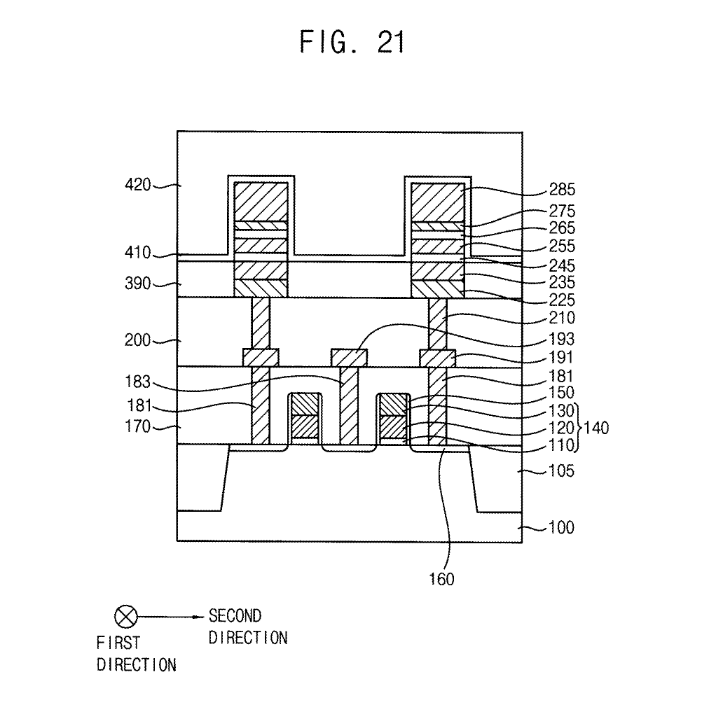

Referring to FIG. 20, the hard mask layer 280 may be etched to form a hard mask 285, and the capping layer 270, the second tunnel barrier layer 260, the free layer 250 and the first tunnel barrier layer 240 may be sequentially etched using the hard mask 285 as an etching mask. Thus, a first tunnel barrier layer pattern 245, a free layer pattern 255, a second tunnel barrier layer pattern 265 and a capping layer pattern 275 may be formed.

A plurality of hard masks 285 may be formed in the first and second directions. Accordingly, a plurality of first tunnel barrier layer patterns 245, a plurality of free layer patterns 255, a plurality of second tunnel barrier layer patterns 265 and a plurality of capping layer patterns 275 may be formed in the first and second directions. By the etching process, the first tunnel barrier layer pattern 245 may be formed to contact the top surface of the first pinning layer pattern 235.

Referring to FIG. 21, a third spacer layer 410 and a seventh insulating interlayer 420 may be sequentially formed on the sixth insulating interlayer 390 to cover the first tunnel barrier layer pattern 245, the free layer pattern 255, the second tunnel barrier layer pattern 265, the capping layer pattern 275 and the hard mask 285.

In one example embodiment, the seventh insulating interlayer 420 may have a top surface substantially higher than a top surface of the third spacer layer 410 on the hard mask 285.

The third spacer layer 410 may be formed to include an oxide and/or a nitride, e.g., aluminum oxide (Al₂O₃), silicon oxide or silicon nitride. The seventh insulating interlayer 420 may be formed to include an oxide, e.g., silicon oxide.

Thereafter, processes substantially the same as or similar to those illustrated with reference to FIGS. 7 to 10 and FIG. 1 may be performed. Thus, a second pinning layer pattern 310 and a wiring 360 contacting the top surface thereof may be formed. As a result, the MRAM device may be manufactured as shown in FIG. 17.

As described above, when the first MTJ structure 401 is formed, the lower electrode 225 and the first pinning layer pattern 235 may be formed by a first physical etching process, the first and second barrier layer patterns 245 and 265, the free layer pattern 255 and the capping layer pattern 275 may be formed by a second physical etching process, and the second pinning layer pattern 310 may be formed by a damascene process. That is, the second pinning layer pattern 310 may not be formed together with the patterns of the first MTJ structure 401 thereunder at the same physical etching process, and the patterns of the first MTJ structure 401 thereunder may be formed by at least two independent physical etching processes. Thus, the first MTJ structure 401 may not be short-circuited.

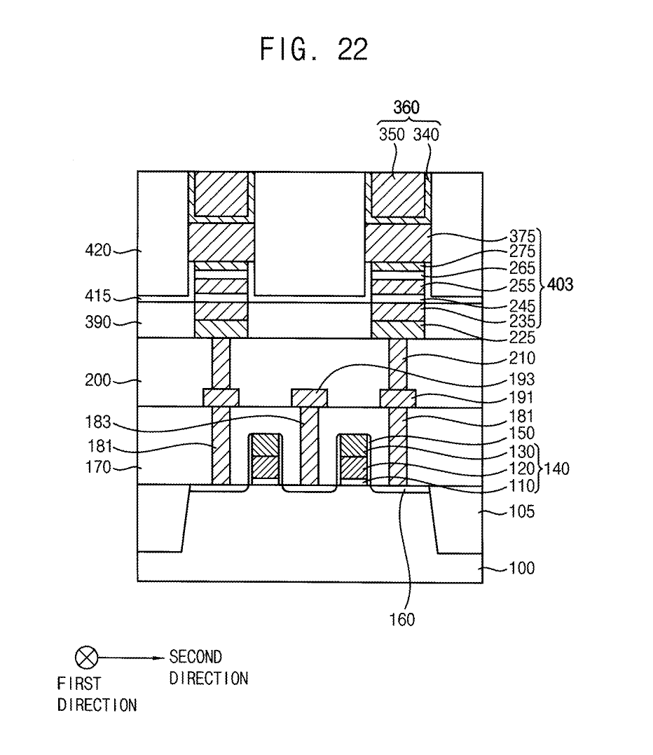

FIG. 22 is a cross-sectional view illustrating an MRAM device in accordance with example embodiments. The MRAM device of FIG. 22 may be substantially the same as or similar to that illustrated with reference to FIG. 17 except for a third pinning layer pattern 375. Thus, like reference numerals refer to like elements, and detailed explanations thereabout may be omitted herein.

Referring to FIG. 22, the MRAM device may include a transistor containing a gate structure 140 and an impurity region 160, a lower electrode 225, a second MTJ structure 403 and a wiring 360. The MRAM device may further include first and third spacers 150 and 415, first to third contact plugs 181, 183 and 210, first and second pads 191 and 193 and first, second, sixth and seventh insulating interlayers 170, 200, 390 and 420.

The second MTJ structure 403 may include a first pinning layer pattern 235, a first tunnel barrier layer pattern 245, a free layer pattern 255, a second tunnel barrier layer pattern 265, a capping layer pattern 275 and a third pinning layer pattern 375 sequentially stacked on the lower electrode 225.

The sixth insulating interlayer 390 may surround the sidewalls of the first pinning layer pattern 235 and the lower electrode 225, and the third spacer 415 may surround sidewalls of the first tunnel barrier layer pattern 245, the free layer pattern 255, the second tunnel barrier layer pattern 265 and the capping layer pattern 275.

The seventh insulating interlayer 420 may surround sidewalls of the wiring 360 and the third pinning layer pattern 375 and an outer sidewall of the third spacer 415.

The MRAM device shown in FIG. 22 may be manufactured by processes that are substantially the same as or similar to those illustrated with reference to FIGS. 18 to 21 except for forming a third pinning layer pattern 375.

First, processes substantially the same as or similar to those illustrated with reference to FIGS. 2 and 3 may be performed. Thus, the transistor including the gate structure 140 and the impurity region 160, the first to third contact plugs 181, 183 and 210, the first and second pads 191 and 193 and first and second insulating interlayers 170 and 200 may be formed.

Processes substantially the same as or similar to those illustrated with reference to FIGS. 18 and 21 may be performed. Thus, the lower electrode 225, the first pinning layer pattern 235, the first tunnel barrier layer pattern 245, the free layer pattern 255, the second tunnel barrier layer pattern 265 and the capping layer pattern 275 may be formed.

Thereafter, processes substantially the same as or similar to those illustrated with reference to FIGS. 12 and 13 may be performed. Thus, the third pinning layer pattern 375 and the wiring 360 may be formed. Alternatively, the third pinning layer pattern 375 and the wiring 360 may be formed by processes substantially the same as or similar to those illustrated with reference to FIGS. 14 and 16.

Therefore, the MRAM device may be manufactured.

As described above, when the second MTJ structure 403 is formed, the lower electrode 225, the first pinning layer pattern 235, the first tunnel barrier layer pattern 245, the free layer pattern 255, the second tunnel barrier layer pattern 265 and the capping layer pattern 275 may be formed by at least two independent physical etching processes, and the third pinning layer pattern 375 may be formed by a physical etching process or a damascene process. As a result, the second MTJ structure 403 may not be electrically short.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concepts as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1. A method of manufacturing a magnetoresistive random access memory (MRAM) device, the method comprising:
forming a lower electrode, a first pinning layer pattern, a tunnel barrier layer pattern and a free layer pattern to be sequentially stacked on a substrate;
forming a first insulating interlayer on the substrate to cover the lower electrode, the first pinning layer pattern, the tunnel barrier layer pattern and the free layer pattern;
etching the first insulating interlayer to form a recess exposing a top surface of the free layer pattern;
forming a second pinning layer pattern to fill at least a portion of the recess; and
forming a wiring on the second pinning layer pattern.

2. The method of claim 1, wherein a thickness of the second pinning layer pattern is larger than a thickness of the first pinning layer pattern.

3. The method of claim 1, wherein the first and second pinning layer patterns have opposite magnetization directions.

4. The method of claim 1, wherein the recess extends in one direction, and
wherein forming the wiring is performed on the second pinning layer pattern to fill a remaining portion of the recess.

5. The method of claim 1, wherein forming the wiring includes:
planarizing an upper portion of the first insulating interlayer until a top surface of the first insulating interlayer is coplanar with a top surface of the second pinning layer pattern;
forming a second insulating interlayer on the planarized first insulating interlayer, the second insulating interlayer having an opening exposing the top surface of the second pinning layer pattern and extending in one direction; and
filling the opening.

6. The method of claim 1, wherein forming the lower electrode, the first pinning layer pattern, the tunnel barrier layer pattern and the free layer pattern includes:
sequentially forming a lower electrode layer, a first pinning layer, a tunnel barrier layer, a free layer and a hard mask on the substrate; and
sequentially patterning the free layer, the tunnel barrier layer, the first pinning layer and the lower electrode layer using the hard mask as an etching mask.

7. The method of claim 6, further comprising forming a first spacer to surround sidewalls of the lower electrode, the first pinning layer pattern, the tunnel barrier layer pattern and the free layer pattern.

8. The method of claim 1, wherein forming the lower electrode, the first pinning layer pattern, the tunnel barrier layer pattern and the free layer pattern includes:
sequentially stacking the lower electrode and the first pinning layer pattern on the substrate;
forming a third insulating interlayer to surround the sidewalls of the lower electrode and the first pinning layer pattern;
forming a tunnel barrier layer, a free layer and the hard mask on the third insulating interlayer and the first pinning layer pattern; and
sequentially patterning the free layer and the tunnel barrier layer using the hard mask as an etching mask.

9. The method of claim 8, further comprising forming a second spacer on the third insulating interlayer to surround the sidewalls of the free layer pattern and the tunnel barrier layer pattern.

10.-15. (canceled)

16. A method of manufacturing a magnetoresistive random access memory (MRAM) device, comprising:
forming a lower electrode on a substrate;
forming a material tunnel junction (MTJ) structure;
forming a hard mask on the MTJ structure;
patterning the MTJ structure and the lower electrode by using the hard mask;
forming a first insulating interlayer on the substrate and the patterned lower electrode, MTJ structure and hard mask;
etching the first insulating interlayer to form a first recess exposing a surface of the MTJ structure;
forming a second pinning layer pattern to fill at least a portion of the recess; and
forming a wiring on the second pinning layer pattern.

17. The method of claim 16, wherein forming the MTJ structure comprises:
forming a first pinning layer pattern having a first thickness on the lower electrode;
forming a first tunnel barrier layer pattern on the first pinning layer pattern;
forming a free layer pattern on the tunnel barrier layer pattern;
forming a second tunnel barrier layer pattern on the free layer pattern; and
forming a capping layer pattern on the second tunnel barrier layer pattern; and
forming a second pinning layer on the capping layer pattern.

18. The method of claim 17, wherein the second pinning layer pattern has a thickness that is larger than a thickness of the first pinning layer pattern.

19. The method of claim 17, wherein the first and second pinning layer patterns have opposite magnetization directions.

20. The method of claim 16, wherein forming the wiring comprises:
forming an etch stop layer on the second pinning layer pattern;
forming a second insulating interlayer on the etch stop layer;
etching the second insulating interlayer to form a second recess having a bottom surface and side walls to expose a surface of the second pinning layer pattern;
forming a barrier layer along the bottom surface and the side walls of the second recess; and
forming a metal layer pattern on the barrier layer in the second recess.

21. The method of claim 16, wherein the second pinning layer pattern and the wiring extend in a same direction.

22. The method of claim 17, further comprising forming a hard mask on the capping layer pattern before forming the first insulating interlayer.

23. The method of claim 16, further comprising forming a spacer layer on the substrate, on a surface of the hard mask, and on side walls of the lower electrode, the MTJ structure, the capping layer pattern and the hard mask before forming the first insulating interlayer.

24. The method of claim 23, wherein etching the first insulating interlayer comprises etching at least a portion of the spacer layer and of the hard mask.

25. The method of claim 24, wherein etching the first insulating interlayer comprises planarizing the spacer layer and the hard mask.

26. The method of claim 22, wherein forming the lower electrode, the first pinning layer pattern, the tunnel barrier layer pattern and the free layer pattern includes:
sequentially forming the lower electrode layer, the first pinning layer, the tunnel barrier layer, the free layer and the hard mask on the substrate; and
sequentially patterning the free layer, the tunnel barrier layer, the first pinning layer and the lower electrode layer using the hard mask as an etching mask.
